(19) United States
(12) Patent Application Publication
(10) Pub. No.: US 2025/0057012 A1
(43) Pub. Date: Feb. 13, 2025

(54) DISPLAY DEVICE

(71) Applicant: Samsung Display Co., LTD., Yongin-si (KR)

(72) Inventors: Je Won YOO, Yongin-si (KR); Chang Mok KIM, Yongin-si (KR); Dong Jo KIM, Yongin-si (KR); Hyun KIM, Yongin-si (KR); Seung Min LEE, Yongin-si (KR); Dan Bi CHOI, Yongin-si (KR)

(73) Assignee: Samsung Display Co., LTD., Yongin-si (KR)

(21) Appl. No.: 18/626,640

(22) Filed: Apr. 4, 2024

(30) Foreign Application Priority Data
Aug. 10, 2023 (KR) 10-2023-0104526

(51) Int. Cl. H10K 59/80; H10K 77/10

(52) U.S. Cl. CPC H10K 59/873; H10K 77/111

(57) ABSTRACT

A display device including a first substrate including a display area and a non-display area surrounding the display area, a second substrate disposed on the first substrate, a display element layer disposed on the second substrate and overlapping the display area, a first encapsulation layer disposed on the display element layer, overlapping the non-display area, and including an inorganic material, and a second encapsulation layer disposed on the first encapsulation layer, including a concavo-convex structure, and including an inorganic material. The first substrate includes a first surface overlapping an edge portion of the first substrate and facing the second substrate, and a first inclined surface extended to the first surface. An inclination angle formed by the first surface and the first inclined surface is an obtuse angle, and the first inclined surface overlaps the second encapsulation layer in a direction perpendicular to the first substrate.

### CROSS-REFERENCE TO RELATED APPLICATION(S)

This application claims priority to and benefits of Korean Patent Application No. 10-2023-0104526 under 35 U.S.C. § 119, filed on Aug. 10, 2023 in the Korean Intellectual Property Office, the entire contents of which are incorporated herein by reference.

### BACKGROUND

### 1. Technical Field

The disclosure relates to a display device.

### 2. Description of the Related Art

As information society develops, the demand for a display device for displaying an image is increasing in various forms. The display device may be a flat panel display, such as a liquid crystal display, a field emission display, or a light emitting display panel.

The display device may include a display area for displaying images and a non-display area disposed around the display area, for example, to surround the display area. Recently, a width of the non-display area has been gradually reduced to increase immersion in the display area and enhance the aesthetics of the display device.

### SUMMARY

Aspects of the disclosure provide a display device for solving etching defects that occur during substrate etching.

However, aspects of the disclosure are not restricted to those set forth herein. The above and other aspects of the disclosure will become more apparent to one of ordinary skill in the art to which the disclosure pertains by referencing the detailed description of the disclosure given below.

An embodiment of a display device may include a first substrate including a display area and a non-display area surrounding the display area, a second substrate disposed on the first substrate, a display element layer disposed on the second substrate and overlapping the display area, a first encapsulation layer disposed on the display element layer, overlapping the non-display area, and including an inorganic material, and a second encapsulation layer disposed on the first encapsulation layer, including a concavo-convex structure, and including an inorganic material. The first substrate may include a first surface overlapping an edge portion of the first substrate and facing the second substrate, and a first inclined surface extending to the first surface. An inclination angle formed by the first surface and the first inclined surface may be an obtuse angle, and the first inclined surface may overlap the second encapsulation layer in a direction perpendicular to the first substrate.

The first inclined surface and the second substrate may form an undercut.

The undercut may overlap the second encapsulation layer in the direction perpendicular to the first substrate.

The second encapsulation layer may completely cover the first encapsulation layer.

The second encapsulation layer may include an inorganic material having acid resistance against a fluorine-based etchant.

The second encapsulation layer may include amorphous silicon.

The second encapsulation layer may include a plurality of first layers including the concavo-convex structure and that are spaced apart from each other in a direction parallel to the first substrate, a second layer completely covering the plurality of first layers and including the concavo-convex structure, and a third layer disposed on the second layer and including the concavo-convex structure.

The third layer may have higher hydrophobicity than the plurality of first layers.

The third layer may include carbon, fluorine, and hydrogen ions.

The second layer may physically contact the first encapsulation layer.

The first substrate may include a second surface facing the first surface and a second inclined surface overlapping the edge portion of the first substrate and extended to the second surface, and an inclination angle formed by the second surface and the second inclined surface is an obtuse angle.

The second inclined surface may overlap the second encapsulation layer in the direction perpendicular to the first substrate.

A thickness of the second encapsulation layer in the direction perpendicular to the first substrate may be about 0.2 μm or less.

The second encapsulation layer may overlap the display area and the non-display area in plan view, and the second encapsulation layer may completely cover the first encapsulation layer in plan view.

The second encapsulation layer may overlap the edge portion of the first substrate and may cover a side surface of the second substrate.

The second encapsulation layer may be disposed in a mesh shape to overlap the non-display area while exposing the display area in plan view.

The second encapsulation layer may overlap the edge portion of the first substrate and cover a side surface of the second substrate.

An embodiment of a display device may include a first substrate including a main area and a pad area, a second substrate disposed on the first substrate and including a bending area disposed between the main area and the pad area, a display element layer disposed on the second substrate and overlapping the main area, a first encapsulation layer disposed on the display element layer and including an inorganic material, and a second encapsulation layer disposed on the first encapsulation layer, including a concavo-convex structure, and including an inorganic material. The first substrate may include a first sub-substrate and a second sub-substrate spaced apart from each other with the bending area disposed between the first sub-substrate and the second sub-substrate. The first sub-substrate may include a surface facing the second substrate, and an inclined surface facing the bending area and extended to the surface. The first sub-substrate and the second encapsulation layer may overlap each other in a direction perpendicular to the first substrate.

An inclination angle formed by the first inclined surface and the first surface may be an obtuse angle, and the second substrate and the first inclined surface may form an undercut.

The first sub-substrate may include a second inclined surface opposing the first inclined surface, the second inclined surface may be extended to the first surface in a direction opposite to a direction in which the first inclined surface may be disposed, an inclination angle formed by the first surface and the second inclined surface may be an obtuse angle, and the second inclined surface and the second encapsulation layer may overlap each other in the direction perpendicular to the first substrate.

Details of other embodiments are included in the detailed description and drawings.

According to the display device according to an embodiment of the disclosure, etching defects of the display device may be solved by applying the thin film encapsulation layer having acid resistance and hydrophobicity to prevent the etchant used during substrate etching from permeating into the display panel.

However, the effects of the embodiments are not restricted to the one set forth herein. The above and other effects of the embodiments will become more apparent to one of ordinary skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment;

FIG. 2 is a schematic cross-sectional view of the display device of FIG. 1;

FIG. 3 is a schematic cross-sectional view illustrating an example of the display device in which a display panel of FIG. 2 is bent;

FIG. 4 is a schematic plan view of the display panel of FIG. 2;

FIG. 5 is an enlarged schematic plan view of area ‘A’ of FIG. 4;

FIG. 6 is a schematic cross-sectional view of the display device taken along line X1-X1′ of FIG. 5;

FIG. 7 is an enlarged schematic cross-sectional view of area ‘C’ of FIG. 6;

FIG. 8 is an enlarged schematic cross-sectional view of area ‘E’ of FIG. 7;

FIG. 9 is an enlarged schematic cross-sectional view of area ‘G’ of FIG. 8;

FIG. 10 is a schematic plan view of an area covered by a fourth encapsulation layer in FIG. 4;

FIG. 11 is an enlarged schematic cross-sectional view of area ‘C’ of FIG. 6 according to another embodiment;

FIG. 12 is an enlarged schematic cross-sectional view of area ‘C’ of FIG. 6 according to still another embodiment;

FIG. 13 is a schematic plan view of an area covered by a fourth encapsulation layer of FIG. 12; and

FIG. 14 is an enlarged schematic cross-sectional view of area ‘C’ in FIG. 6 according to still another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element (or a region, a layer, a portion, or the like) is referred to as being “on”, “connected to” or “coupled to” another element in the specification, it can be directly disposed on, connected or coupled to another element mentioned above, or intervening elements may be present disposed therebetween. In contrast, when an element is referred to as being “directly on” another element, there may be no intervening elements present.

It will be understood that the terms “connected to” or “coupled to” may include a physical and/or electrical connection or coupling.

It will be understood that, although the terms “first,” “second,” “third,” or the like may be used herein to describe various elements, these elements should not be limited by these terms. These terms are only used to distinguish one element from another element. For example, “a first element” may be referred to as “a second element” or “a third element,” and similarly “a second element” or “a third element” may be referred to as a “first element” without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

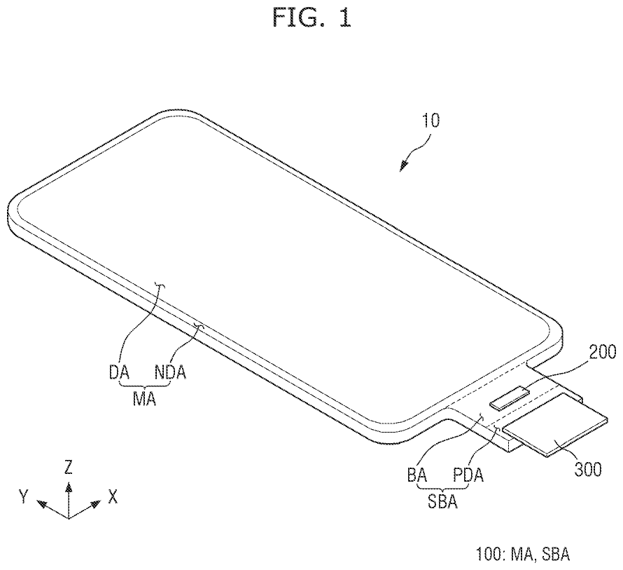

FIG. 1 is a schematic perspective view of a display device according to an embodiment.

Referring to FIG. 1, a display device 10 according to an embodiment may be a device that displays a moving image or a still image, and may be used as a display screen of each of various products such as a television, a laptop computer, a monitor, a billboard, and an Internet of Things (IOT) device, as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

The display device 10 according to an embodiment may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (LED). Hereinafter, it is mainly described that the display device 10 is the organic light emitting display device, but the disclosure is not limited thereto.

The display device 10 according to an embodiment may include a display panel 100, a display driver 200, and a circuit board 300.

The display panel 100 may be formed in a rectangular plane having short sides in a first direction (X-axis direction) and long sides in a second direction (Y-axis direction) intersecting the first direction (X-axis direction). A corner where the short side in the first direction (X-axis direction) and the long side in the second direction (Y-axis direction) meet may be formed at a right angle or may be rounded to have a predetermined or selected curvature. The planar shape of the display panel 100 is not limited to the quadrangular shape, and may be other polygonal shapes, a circular shape, or an elliptical shape.

The display panel 100 may be formed to be flat, but is not limited thereto. For example, the display panel 100 may include curved surface portions formed at left and right distal ends thereof and having a constant curvature or a variable curvature. The display panel 100 may be flexibly formed to be curved, bent, folded, or rolled.

The display panel 100 may include a main area MA and a sub-area SBA. The main area MA may include a display area DA including pixels displaying an image, and a non-display area NDA disposed around the display area DA.

The display area DA may emit light from light emitting areas or opening areas to be described later. For example, the display area DA may include a pixel circuit including switching elements, a pixel definition film defining the light emitting areas or the opening areas, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto. In the following drawings, it is illustrated that the self-light emitting element is an organic light emitting diode.

The non-display area NDA may be an area outside the display area DA. The non-display area NDA may be defined as an edge area of the main area MA of the display panel 100. The non-display area NDA may include wirings connecting the display driver 200 and the pixels PX.

The sub-area SBA may be an area extending from a side of the main area MA. The sub-area SBA may include a bending area BA and a pad area PDA.

The bending area BA may include a flexible material that may be bent, folded, rolled, or the like. As an example, in case that the display panel 100 overlapping the bending area BA is bent, the display driver 200 and the circuit board 300 positioned (disposed) in the pad area PDA may overlap the main area MA in a third direction (Z-axis direction).

The pad area PDA may include the display driver 200 and the circuit board 300. Although not illustrated, the pad area PDA may include a display pad connected to the circuit board 300. In another embodiment, the sub-area SBA may be omitted, and the display driver 200 and the display pad may also be positioned in the non-display area NDA.

The display driver 200 may output signals and voltages for driving the display panel 100. The display driver 200 may supply data voltages to data lines. The display driver 200 may supply a power voltage to a power line and may supply a gate control signal to a gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the display pad of the display panel 100 using an anisotropic conductive film (ACF). Lead lines of the circuit board 300 may be electrically connected to the display pad of the display panel 100. The circuit board 300 may be a flexible film such as a flexible printed circuit board, a printed circuit board, or a chip on film.

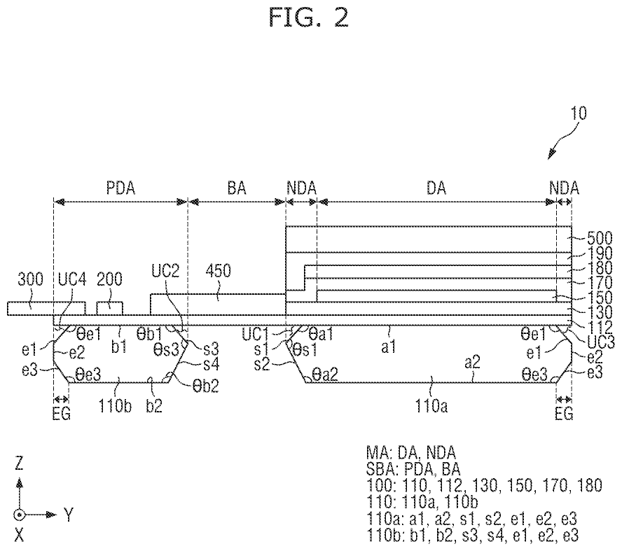

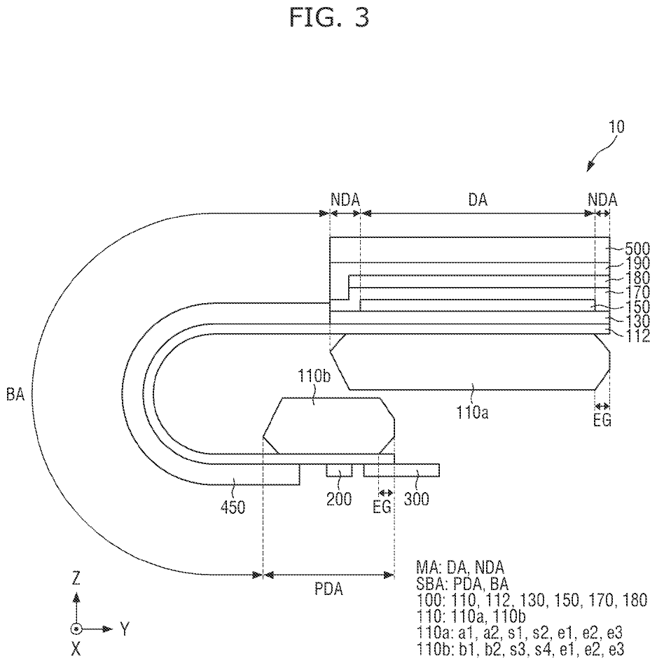

FIG. 2 is a schematic cross-sectional view of the display device 10 of FIG. 1. FIG. 3 is a schematic cross-sectional view illustrating an example of the display device 10 in which a display panel 100 of FIG. 2 is bent.

Referring to FIG. 2, the display device 10 according to an embodiment may include a display panel 100, a polarizing film 190, and a cover window 500. The display panel 100 may include a first substrate 110, a second substrate 112, a thin film transistor layer 130, a display element layer 150, a thin film encapsulation layer 170, and a touch sensor layer 180.

The first substrate 110 may have a hard material. For example, the first substrate 110 may be made of glass. The first substrate 110 may be made of ultra-thin glass (UTG) having a thickness of about 200 μm or less.

A portion of the first substrate 110 included in the specification overlapping the bending area BA may be etched during the manufacturing process to secure the bending area BA. Accordingly, the first substrate 110 may be divided into a first sub-substrate 110a and a second sub-substrate 110b. The first sub-substrate 110a and the second sub-substrate 110b may be spaced apart from each other while exposing the bending area BA. Specifically, the first sub-substrate 110a may overlap the display area DA and the non-display area NDA of the main area MA, and the second sub-substrate 110b may overlap the pad area PDA of the sub-area SBA. The first substrate 110 may not overlap the bending area BA, but is not limited thereto. Depending on the manufacturing process, a portion of the first substrate 110 may also overlap the bending area BA.

In some embodiments, the first sub-substrate 110a may include an upper surface a1, a lower surface a2, a first inclined surface s1, and a second inclined surface s2. The upper surface a1 of the first sub-substrate 110a may be a surface physically contacting the second substrate 112, and the lower surface a2 of the first sub-substrate 110a may be a surface facing the upper surface a1. The first inclined surface s1 and the second inclined surface s2 of the first sub-substrate 110a may be positioned toward the bending area BA, and the upper surface a1 and the lower surface a2 may extend by the first inclined surface s1 and the second inclined surface s2.

In some embodiments, an inclination angle θa1 formed by the first inclined surface s1 and the upper surface a1 of the first sub-substrate 110a and an inclination angle θa2 formed by the second inclined surface s2 and the lower surface a2 of the first sub-substrate 110a may be an obtuse angle. An inclination angle θs1 formed by the first and second inclined surfaces s1 and s2 may be an acute angle, an obtuse angle, or a right angle. A size of the inclination angle θs1 formed by the first and second inclined surfaces s1 and s2 may be adjusted by an etching process of the bending area BA included in the manufacturing process of the display device 10.

In some embodiments, an undercut UC1 may be formed between the first inclined surface s1 included in the first sub-substrate 110a and the second substrate 112. The undercut UC1 formed between the first sub-substrate 110a and the second substrate 112 may overlap the thin film transistor layer 130, the thin film encapsulation layer 170, the touch sensor layer 180, the polarizing film 190, and the cover window 500 positioned thereon in the third direction (Z-axis direction).

The first inclined surface s1 and the second inclined surface s2 included in the first sub-substrate 110a of an embodiment may overlap the second substrate 112, the thin film transistor layer 130, the thin film encapsulation layer 170, the touch sensor layer 180, the polarizing film 190, and the cover window 500 positioned on the first substrate 110 in the third direction (Z-axis direction).

In some embodiments, the second sub-substrate 110b may include an upper surface b1, a lower surface b2, a first inclined surface s3, and a second inclined surface s4. The upper surface b1 of the second sub-substrate 110b may be a surface physically contacting the second substrate 112, and the lower surface b2 of the second sub-substrate 110b may be a surface facing the upper surface b1. The first inclined surface s3 and the second inclined surface s4 of the second sub-substrate 110b may be positioned toward the bending area BA, and the upper surface b1 and the lower surface b2 may extend by the first inclined surface s3 and the second inclined surface s4.

In some embodiments, an inclination angle θb1 formed by the first inclined surface s3 and the upper surface b1 of the second sub-substrate 110b and an inclination angle θb2 formed by the second inclined surface s4 and the lower surface b2 of the second sub-substrate 110b may be an obtuse angle. An inclination angle θs3 formed by the first and second inclined surfaces s3 and s4 may be an acute angle, an obtuse angle, or a right angle. The inclination angle θs3 formed by the first and second inclined surfaces s3 and s4 may be adjusted by an etching process of the bending area BA included in the manufacturing process of the display device 10.

In some embodiments, an undercut UC2 may be formed between the first inclined surface s3 included in the second sub-substrate 110b and the second substrate 112. The undercut UC2 formed between the second sub-substrate 110b and the second substrate 112 may overlap a bending protection layer 450 positioned thereon in the third direction (Z-axis direction).

The first inclined surface s3 and the second inclined surface s4 of the second sub-substrate 110b of an embodiment may overlap the second substrate 112 and the bending protection layer 450 disposed on the first substrate 110 in the third direction (Z-axis direction).

In some embodiments, the display panel 100 may include an edge portion EG. The edge portion EG may refer to an end portion of the display panel 100. In other words, the edge portion EG of the display panel 100 may refer to a portion overlapping an outer portion of the display device 10. Specifically, the edge portion EG of the display panel 100 may be an outer portion surrounding the display device 10 by overlapping the non-display area NDA, the bending area BA, and the pad area PDA in plan view.

In some embodiments, the first substrate 110 may include a first edge surface e1, a second edge surface e2, and a third edge surface e3 overlapping the edge portion EG of the display panel 100. As an example, the first sub-substrate 110a of the display device 10 may include a first edge surface e1, a second edge surface e2, and a third edge surface e3 overlapping the non-display area NDA, and the second sub-substrate 110b may include a first edge surface e1, a second edge surface e2, and a third edge surface e3 overlapping the pad area PDA. According to an embodiment, the first edge surface e1 and the third edge surface e3 may be connected by the second edge surface e2, and according to another embodiment, the first edge surface e1 and the third edge surface e3 may also be directly connected.

The first edge surface e1, the second edge surface e2, and the third edge surface e3 overlapping the edge portion EG of the display panel 100 may be formed by the etching process included in the manufacturing process of the display device 10. As described above, during the manufacturing process of the display device 10, a portion of the first substrate 110 overlapping the bending area BA may be removed by the etching process, and at the same time, a portion overlapping the edge portion EG of the display panel 100 may also be etched.

In some embodiments, the first edge surface e1 and the third edge surface e3 may be inclined surfaces. As an example, an inclination angle θe1 formed by the upper surface a1 of the first sub-substrate 110a and the first edge surface e1 and an inclination angle θe3 formed by the lower surface a2 of the first sub-substrate 110a and the third edge surface e3 may be an obtuse angle. An inclination angle θe1 formed by the upper surface a1 of the second sub-substrate 110b and the first edge surface e1 and an inclination angle θe3 formed by the lower surface b2 of the second sub-substrate 110b and the third edge surface e3 may be an obtuse angle.

In some embodiments, an undercut UC3 may be formed between the second substrate 112 and the first edge surface e1 of the first sub-substrate 110a. The undercut UC3 formed between the second substrate 112 and the first sub-substrate 110a may overlap the second substrate 112, the thin film transistor layer 130, the thin film encapsulation layer 170, the touch sensor layer 180, the polarizing film 190, and the cover window 500 positioned thereon in the third direction (Z-axis direction). An undercut UC4 may be formed between the second substrate 112 and the first edge surface e1 of the second sub-substrate 110b. The undercut UC4 formed between the second substrate 112 and the second sub-substrate 110b may overlap the second substrate 112 and the circuit board 300 positioned thereon in the third direction (Z-axis direction).

The second substrate 112 may be positioned on the first substrate 110. The second substrate 112 may be positioned to overlap the main area MA and the sub-area SBA. The second substrate 112 may have a soft material. The second substrate 112 may be made of a polymer resin having a thickness smaller than that of the first substrate 110. For example, the second substrate 112 may have a thickness of about 20 μm. The second substrate 112 may be formed of an organic material such as an acryl resin, an epoxy resin, a phenolic resin, a polyamide resin, a polyimide resin, or the like. The second substrate 112 may be referred to as a plastic substrate because of being made of the polymer resin.

The thin film transistor layer 130 may be positioned on the second substrate 112. The thin film transistor layer 130 may include thin film transistors TFT and wirings. The thin film transistor layer 130 may be positioned to overlap the display area DA and the non-display area NDA of the main area MA.

The display element layer 150 may be disposed on the thin film transistor layer 130. The display element layer 150 may be a layer that displays an image. The display element layer 150 may include a light emitting element overlapping the display area DA of the main area MA to emit light through a pixel electrode, a light emitting layer, and a common electrode, and wirings driving the light emitting element.

The thin film encapsulation layer 170 may be disposed on the display element layer 150. The thin film encapsulation layer 170 may be positioned to overlap the display area DA and the non-display area NDA of the main area MA. The thin film encapsulation layer 170 may prevent oxygen or moisture from permeating into the display element layer 150. The thin film encapsulation layer 170 may prevent the etchant from physically contacting the display panel 100 during the etching process of the first substrate 110 described above. The thin film encapsulation layer 170 may include at least one inorganic film and at least one organic film. The organic film of the thin film encapsulation layer 170 may protect the display element layer 150 from foreign substances such as dust.

The touch sensor layer 180 may be disposed on the thin film encapsulation layer 170. The touch sensor layer 180 may be positioned to overlap the display area DA and the non-display area NDA of the main area MA. The touch sensor layer 180 may include a touch wiring, a touch buffer layer, a touch insulation layer, and a touch protection layer. The touch sensor layer 180 may sense a user's touch using touch wirings.

The polarizing film 190 may be disposed on the display panel 100 to reduce reflection of external light. The polarizing film 190 may be positioned to overlap the display area DA and the non-display area NDA of the main area MA. The polarizing film 190 may include a first base member, a linear polarizing plate, a phase retardation film such as a quarter-waver (λ/4) plate, and a second base member. The first base member, the phase retardation film, the linear polarizing plate, and the second base member of the polarizing film 190 may be stacked on each other on the display panel 100.

The cover window 500 may be disposed on the polarizing film 190. The cover window 500 may be positioned to overlap the display area DA and the non-display area NDA of the main area MA. The cover window 500 may be attached onto the polarizing film 190 by a transparent adhesive member such as an optically clear adhesive (OCA) film.

The bending protection layer 450 may be positioned on the second substrate 112 to overlap the bending area BA. In case that the display panel 100 is bent, the bending protection layer 450 may protect a lower structure overlapping the bending area BA. According to an embodiment, the bending protection layer 450 may also overlap the pad area PDA.

The bending protection layer 450 may include a synthetic resin. As an example, the bending protection layer 450 may include at least one of acrylonitrile butadiene styrene copolymer (ABS), urethaneacrylate (UA), polyurethane (PU), polyethylene (PE), ethylene vinyl acetate (EVA), and polyvinyl chloride (PVC).

The display driver 200 and the circuit board 300 may be positioned on the second substrate 112 to overlap the pad area PDA. The display driver 200 may be positioned between the bending protection layer 450 and the circuit board 300 in the second direction (Y-axis direction), and may be positioned to be spaced apart from the bending protection layer 450 and the circuit board 300 in the second direction (Y-axis direction).

Referring to FIG. 3, in the display device 10, a portion of the display panel 100 overlapping the bending area BA may be bent. In case that the display panel 100 overlapping the bending area BA is bent, the pad area PDA of the display device 10 may overlap the display area DA and the non-display area NDA in the third direction (Z-axis direction). In case that the display device 10 is bent, the first sub-substrate 110a and the second sub-substrate 110b may overlap each other in the third direction (Z-axis direction).

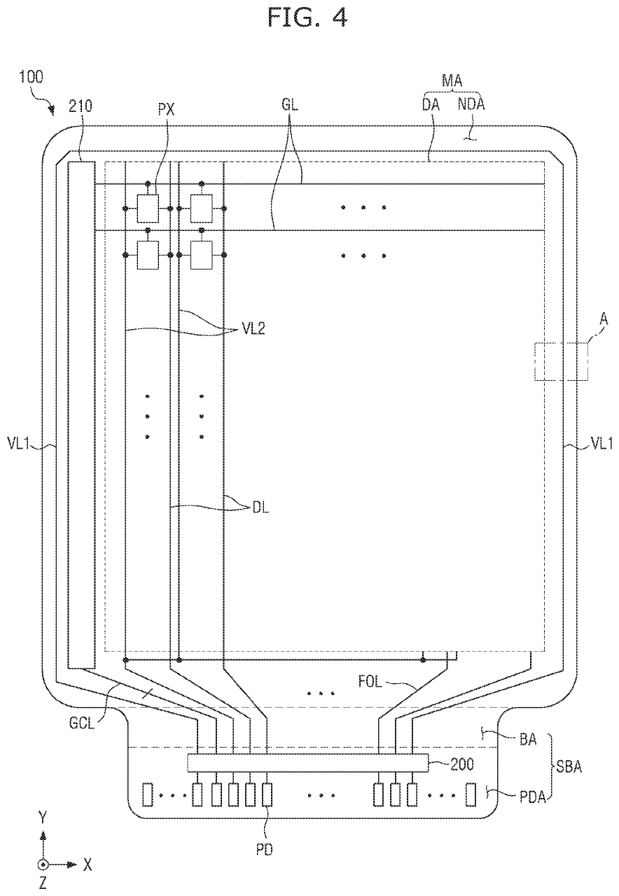

FIG. 4 is a schematic plan view of the display panel 100 of FIG. 2.

Referring to FIG. 4, the display panel 100 may include pixels PX, gate lines GL, data lines DL, and second power lines VL2 overlapping the display area DA of the main area MA.

Each of the pixels PX may be defined as a minimum unit emitting light. Each of the pixels PX may constitute light emitting areas EA1, EA2, EA3, and EA4 to be described later.

The gate lines GL may supply a gate signal received from a gate driver 210 to the pixels PX. The gate lines GL may extend in the first direction (X-axis direction) and may be spaced apart from each other in the second direction (Y-axis direction) intersecting the first direction (X-axis direction).

The data lines DL may supply the data voltages received from the display driver 200 to the pixels PX. The data lines DL may extend in the second direction (Y-axis direction) and may be spaced apart from each other in the first direction (X-axis direction).

The second power line VL2 may supply the power voltage received from the display driver 200 to the pixels PX. Here, the power voltage may be at least one of a driving voltage, an initialization voltage, and a reference voltage. The second power lines VL2 may extend in the second direction (Y-axis direction) and may be spaced apart from each other in the first direction (X-axis direction).

The display panel 100 may include a first power line VL1, a gate driver 210, fan-out lines FOL, and gate control lines GCL overlapping the non-display area NDA of the main area MA.

The gate driver 210 may generate gate signals based on the gate control signal, and may sequentially supply the gate signals to the gate lines GL according to a set order.

The first power line VL1 may surround the display area DA and may be disposed in the non-display area NDA. The first power line VL1 may supply the power voltage received from the display driver 200 to the pixels PX. Here, the power voltage may be a low-potential power voltage.

The fan-out lines FOL may extend from the display driver 200 to the display area DA. The fan-out lines FOL may supply the data voltage received from the display driver 200 to the data lines DL.

The gate control line GCL may extend from the display driver 200 to the gate driver 210. The gate control line GCL may supply the gate control signal received from the display driver 200 to the gate driver 210. It is illustrated in the drawing that the gate driver 210 is disposed only in the non-display area NDA disposed on the left side of the display area DA, but the disclosure is not limited thereto. In another embodiment, the display device 10 may also include gate drivers 210 respectively disposed on the left and right sides of the display area DA.

The display panel 100 may include the display driver 200 and display pads PD overlapping the pad area PDA of the sub-area SBA.

The display driver 200 may output signals and voltages for driving the display panel 100 to the fan-out lines FOL. The display driver 200 may supply the data voltage to the data lines DL through the fan-out lines FOL. The data voltage may be supplied to the pixels PX and may control luminance of the pixels PX. The display driver 200 may supply the gate control signal to the gate driver 210 through the gate control lines GCL.

The display pads PD may be connected to a graphic system through the circuit board 300. The display pad portions DP may be connected to the circuit board 300 to receive digital video data and supply the digital video data to the display driver 200.

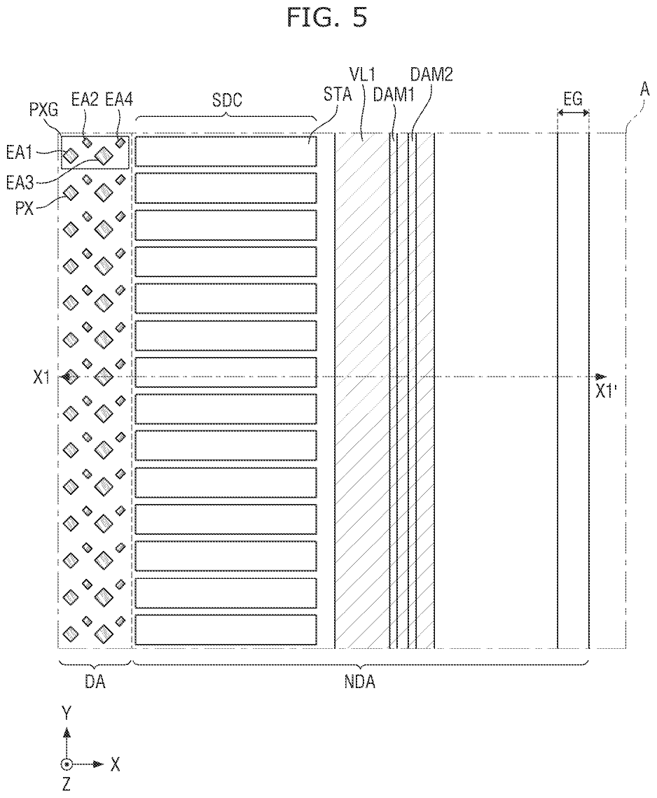

FIG. 5 is an enlarged schematic plan view of area ‘A’ of FIG. 4.

Referring to FIG. 5, light emitting areas EA1, EA2, EA3, and EA4 may be positioned in the display area DA. The light emitting areas EA1, EA2, EA3, and EA4 may include a first light emitting area EA1 emitting light of a first color, a second light emitting area EA2 emitting light of a second color, and a third light emitting area EA3 emitting light of a third color. For example, the light of the first color may be light in a red wavelength band of about 600 nm to about 750 nm, the light of the second color may be light in a green wavelength band of about 480 nm to about 560 nm, and the light of the third color may be light in a blue wavelength band of about 370 nm to about 460 nm, but is not limited thereto.

Pixels PX including at least one first light emitting area EA1, at least one second light emitting area EA2, at least one third light emitting area EA3, and at least one fourth light emitting area EA4 adjacent to each other may constitute a pixel group PXG. The pixel group PXG may be a minimum unit emitting white light. However, the type and/or number of light emitting areas EA1, EA2, EA3, and EA4 constituting each pixel group PXG may be variously changed according to embodiments.

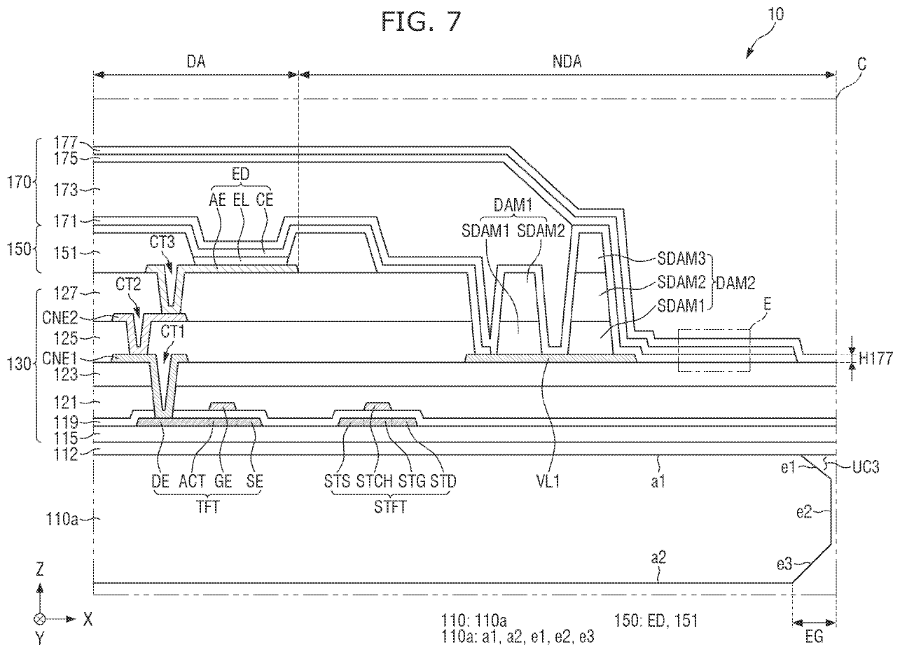

The light emitting areas EA1, EA2, EA3, and EA4 may be defined by a pixel definition layer (‘151’ in FIG. 7) to be described later.

It is illustrated in FIG. 5 that the second light emitting area EA2 and the fourth light emitting area EA4 emit light of the same color, for example, light of the second color, but the disclosure is not limited thereto. The second light emitting area EA2 and the fourth light emitting area EA4 may emit light of different colors. For example, the second light emitting area EA2 may emit light of a second color, and the fourth light emitting area EA4 may emit light of a fourth color. It is illustrated that each of the first light emitting areas EA1, the second light emitting areas EA2, the third light emitting areas EA3, and the fourth light emitting areas EA4 has a rectangular planar shape, but the disclosure is not limited thereto. For example, each of the first light emitting areas EA1, the second light emitting areas EA2, the third light emitting areas EA3, and the fourth light emitting areas EA4 may have polygonal, circular, or elliptical planar shapes other than the quadrangular shape.

In some embodiments, the second light emitting areas EA2 and the fourth light emitting areas EA4 may be alternately disposed in the first direction (X-axis direction). The second light emitting areas EA2 may be disposed in the second direction (Y-axis direction), and the fourth light emitting areas EA4 may be disposed in the second direction (Y-axis direction). The first light emitting areas EA1 and the third light emitting areas EA3 may be alternately disposed in the first direction (X-axis direction). The first light emitting areas EA1 may be disposed in the second direction (Y-axis direction). The third light emitting areas EA3 may be disposed in the second direction (Y-axis direction). Each of the first light emitting areas EA1 and the third light emitting areas EA3 may have a square planar shape, but is not limited thereto.

A scan driver SDC, a first power line VL1, a first dam DAM1, and a second dam DAM2 may be disposed in the non-display area NDA.

The scan driver SDC may include stages STA. The stages STA may extend in the first direction (X-axis direction) and be connected to respective scan lines positioned in the display area DA. For example, the stages STA may be connected to the scan lines of the display area DA in a one-to-one manner. The stages STA may sequentially apply scan signals to scan lines.

The first power line VL1 may be disposed outside the scan driver SDC. For example, the first power line VL1 may be disposed closer to the edge portion EG of the display panel 100 than the scan driver SDC. The first power line VL1 may extend in the second direction (Y-axis direction) in the non-display area NDA on the left side of the display panel 100.

The first power line VL1 may be electrically connected to the pixels PX positioned in the display area DA, and thus the pixels PX may be supplied with the power voltage.

The first dam DAM1 and the second dam DAM2 may be structures for preventing the second encapsulation layer 173 of the thin film encapsulation layer 170L from overflowing into the edge portion EG of the display panel 100. The first dam DAM1 and the second dam DAM2 may be positioned in the non-display area NDA and may surround the display area DA. The second dam DAM2 may be disposed outside the first dam DAM1. In other words, the second dam DAM2 may surround the first dam DAM1. The first dam DAM1 may be disposed closer to the scan driver SDC than the second dam DAM2, and the second dam DAM2 may be disposed closer to the edge portion EG of the display panel 100 than the first dam DAM1.

It is illustrated in FIG. 5 that the first dam DAM1 and the second dam DAM2 are disposed on the first power line VL1, but the disclosure is not limited thereto. For example, either one of the first dam DAM1 and the second dam DAM2 may not be disposed on the first power line VL1. In another embodiment, neither the first dam DAM1 nor the second dam DAM2 may be disposed on the first power line VL1. In this case, the first dam DAM1 and the second dam DAM2 may be disposed outside the first power line VL1.

It is illustrated in FIG. 5 that the display panel 100 includes two dams DAM1 and DAM2, but the disclosure is not limited thereto. In some embodiments, the display panel 100 may also include three or more dams.

As described above, the edge portion EG of the display panel 100 may be a portion overlapping the non-display area NDA and surrounding the outer portion of the display device 10.

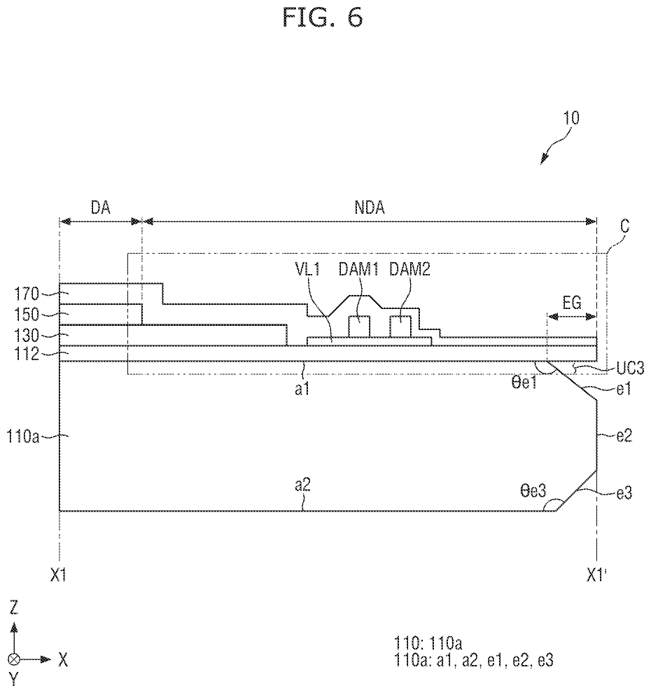

FIG. 6 is a schematic cross-sectional view of the display device 10 taken along line X1-X1′ of FIG. 5. FIG. 7 is an enlarged schematic cross-sectional view of area ‘C’ of FIG. 6.

A schematic cross-sectional structure overlapping the display area DA and the non-display area NDA of the display device 10 will be described with reference to FIGS. 6 and 7.

As described above, a portion of the first substrate 110 included in the display device 10 overlapping the bending area BA and the edge portion EG may be etched through the etching process during the manufacturing process. Therefore, the first substrate 110 illustrated in FIGS. 6 and 7 may be the first sub-substrate 110a, and the first sub-substrate 110a may include a first edge surface e1, a second edge surface e2, and a third edge surface e3 overlapping the edge portion EG. An undercut UC3 may be formed between the first edge surface e1 and the second substrate 112 overlapping the edge portion EG. An inclination angle θe1 formed by the upper surface a1 of the first sub-substrate 110a and the first edge surface e1 and an inclination angle θe3 formed by the lower surface a2 of the first sub-substrate 110a and the third edge surface e3 may be an obtuse angle. Other overlapping descriptions will be omitted.

The second substrate 112 may be positioned on the first substrate 110. Since the second substrate 112 has already been mentioned, overlapping descriptions thereof will be omitted.

The thin film transistor layer 130 may be positioned on the second substrate 112. The thin film transistor layer 130 may include a buffer layer 115, a gate insulating layer 119, a thin film transistor TFT, a first insulating layer 121, a second insulating layer 123, a first connection electrode CNE1, a second connection electrode CNE2, a first via layer 125, and a second via layer 127.

The buffer layer 115 may be disposed on the second substrate 112. The buffer layer 115 may be formed of an inorganic material such as a silicon nitride layer, a silicon oxynitride layer, a silicon oxide layer, a titanium oxide layer, and an aluminum oxide layer. In another embodiment, the buffer layer 115 may be formed as multiple films in which layers of a silicon nitride layer, a silicon oxynitride layer, a silicon oxide layer, a titanium oxide layer, and an aluminum oxide layer are stacked on each other.

The thin film transistor TFT may be disposed on the buffer layer 115. The thin film transistor TFT may include a gate electrode GE, an active layer ACT, a source region SE and a drain region DE. The active layer ACT may be formed of polycrystalline silicon, single crystal silicon, low temperature polycrystalline silicon, amorphous silicon, or an oxide semiconductor material. The source region SE and the drain region DE may be conductive regions doped with ions or impurities to have conductivity.

In FIG. 7, a scan thin film transistor STFT of the scan driver SDC is illustrated. The scan thin film transistor STFT may be substantially the same as the thin film transistor TFT. Specifically, the scan thin film transistor STFT may include a scan gate electrode STCH, a scan active layer STG, a scan source region STS, and a scan drain region STD. The scan active layer STG may be formed of polycrystalline silicon, single crystal silicon, low temperature polycrystalline silicon, amorphous silicon, or an oxide semiconductor material. The scan source region STS and the scan drain region STD may be conductive regions doped with ions or impurities to have conductivity. Other descriptions of the scan thin film transistor STFT will be omitted.

The gate insulating layer 119 may be disposed on the active layer ACT of the thin film transistor TFT. The gate insulating layer 119 may separate the gate electrode GE and the active layer ACT. The gate insulating layer 119 may be formed as an inorganic film, for example, a silicon nitride layer, a silicon oxynitride layer, a silicon oxide layer, a titanium oxide layer, or an aluminum oxide layer.

The gate electrode GE of the thin film transistor TFT may be disposed on the gate insulating layer 119. The gate electrode GE of the thin film transistor TFT may overlap the active layer ACT in the third direction (Z-axis direction). The gate electrode GE may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof.

The first insulating layer 121 may be disposed on the gate electrode GE. The first insulating layer 121 may be formed as an inorganic film, for example, a silicon nitride layer, a silicon oxynitride layer, a silicon oxide layer, a titanium oxide layer, or an aluminum oxide layer. The first insulating layer 121 may include inorganic films. The first insulating layer 121 may include a first contact hole CT1.

The second insulating layer 123 may be disposed on the first insulating layer 121. The second insulating layer 123 may be formed as an inorganic film, for example, a silicon nitride layer, a silicon oxynitride layer, a silicon oxide layer, a titanium oxide layer, or an aluminum oxide layer. The second insulating layer 123 may include a first contact hole CT1.

The first connection electrode CNE1 may be disposed on the second insulating layer 123. The first connection electrode CNE1 may be connected to the drain region DE through the first contact hole CT1 penetrating through the gate insulating layer 119, the first insulating layer 121, and the second insulating layer 123. The first connection electrode CNE1 may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof.

The first via layer 125 may be positioned on the first connection electrode CNE1. The first via layer 125 may planarize a profile of the lower structure. The first via layer 125 may be formed as an organic film made of an acryl resin, an epoxy resin, a phenolic resin, a polyamide resin, a polyimide resin, or the like.

The second connection electrode CNE2 may be disposed on the first via layer 125. The second connection electrode CNE2 may be connected to the first connection electrode CNE1 through a second contact hole CT2 penetrating through the first via layer 125. The second connection electrode CNE2 may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof.

The second via layer 127 may be disposed on the second connection electrode CNE2. The second via layer 127 may be formed as an organic film made of an acryl resin, an epoxy resin, a phenolic resin, a polyamide resin, a polyimide resin, or the like.

The display element layer 150 may be disposed on the thin film transistor layer 130. The display element layer 150 may include a light emitting element ED and a pixel definition layer 151.

The light emitting element ED may include a pixel electrode AE, a light emitting layer EL, and a common electrode CE. The light emitting element ED refers to an area in which the pixel electrode AE, the light emitting layer EL, and the common electrode CE are stacked on each other and holes from the pixel electrode AE and electrons from the common electrode CE are bonded to each other in the light emitting layer EL to emit light. In this case, the pixel electrode AE may be an anode electrode, and the common electrode CE may be a cathode electrode.

The pixel electrode AE may be formed on the second via layer 127. The pixel electrode AE may be connected to the second connection electrode CNE2 through a third contact hole CT3 penetrating through the second via layer 127. The pixel electrode AE may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof.

The pixel definition layer 151 may serve to define the light emitting areas EA1, EA2, EA3, and EA4 illustrated in FIG. 5. The pixel definition layer 151 may be formed to expose a partial area of the pixel electrode AE on the second via layer 127. The pixel definition layer 151 may be disposed in the third contact hole CT3. In other words, the third contact hole CT3 may be filled with the pixel definition layer 151. The pixel definition layer 151 may be formed as an organic film made of an acryl resin, an epoxy resin, a phenolic resin, a polyamide resin, a polyimide resin, or the like.

The light emitting layer EL may be formed on the pixel electrode AE. The light emitting layer EL may include an organic material to emit light of a predetermined or selected color. For example, the light emitting layer EL may include a hole transporting layer, an organic material layer, and an electron transporting layer. The organic material layer may include a host and a dopant. The organic material layer may include a material that emits a predetermined or selected light and may be formed of a phosphorescent material or a fluorescent material. The light emitting layers EL may overlap each of the light emitting areas EA1, EA2, EA3, and EA4 illustrated in FIG. 5 and may be spaced apart from each other.

The common electrode CE may be formed on the light emitting layer EL. The common electrode CE may be formed to cover the light emitting layer EL. The common electrode CE may be a common layer commonly formed in each of the light emitting areas EA1, EA2, EA3, and EA4. Although not illustrated in the drawings, a capping layer may also be formed on the common electrode CE.

The common electrode CE may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the common electrode CE is formed of the semi-transmissive conductive material, light emitting efficiency may be increased by a micro cavity.

Referring to FIG. 7, the first power line VL1 may include the same material as the first connection electrode CNE1 and the wirings, and may be disposed on the second insulating layer 123. The first power line VL1 may be formed of a single layer or multiple layers made of at least one of molybdenum (Mo), aluminum (Al), chromium (Cr), gold (Au), titanium (Ti), nickel (Ni), neodymium (Nd), and copper (Cu), or alloys thereof.

The first dam DAM1 and the second dam DAM2 may be disposed on the first power line VL1. The first dam DAM1 may include a first sub-dam SDAM1 and a second sub-dam SDAM2, and the second dam DAM2 may include a first sub-dam SDAM1, a second sub-dam SDAM2, and a third sub-dam SDAM3. The first sub-dam SDAM1 may include the same material as the first via layer 125 and may be disposed on the same layer as the first via layer 125. The second sub-dam SDAM2 may include the same material as the second via layer 127 and may be disposed on the same layer as the second via layer 127. The third sub-dam SDAM3 may include the same material as the pixel definition layer 151 and may be disposed on the same layer as the pixel definition layer 151.

A height of the first dam DAM1 may be lower than a height of the second dam DAM2, but the embodiment of the specification is not limited thereto. The height of the first dam DAM1 may be substantially the same as or higher than the height of the second dam DAM2.

The thin film encapsulation layer 170 may be formed on the display element layer 150. The thin film encapsulation layer 170 may be positioned to overlap the display area DA and the non-display area NDA. In order to prevent oxygen or moisture from permeating into the display element layer 150, the thin film encapsulation layer 170 may include a first encapsulation layer 171 and a third encapsulation layer 175 formed of an inorganic film, and a second encapsulation layer 173 formed of an organic film.

The first encapsulation layer 171 may be disposed on the common electrode CE, the second encapsulation layer 173 may be disposed on the first encapsulation layer 171, and the third encapsulation layer 175 may be disposed on the second encapsulation layer 173. As described above, the second encapsulation layer 173 may not flow to the edge portion EG of the display panel 100 due to the second dam DAM2.

The first encapsulation layer 171 and the third encapsulation layer 175 may be formed as multiple films in which one or more inorganic films of a silicon nitride layer, a silicon oxynitride layer, a silicon oxide layer, a titanium oxide layer, and an aluminum oxide layer are stacked on each other. The second encapsulation layer 173 may be an organic film made of an acryl resin, an epoxy resin, a phenolic resin, a polyamide resin, a polyimide resin, or the like.

The thin film encapsulation layer 170 included in an embodiment may include a fourth encapsulation layer 177 that protects the display panel 100 from being damaged by an etchant. The fourth encapsulation layer 177 may be positioned to overlap the display area DA and the non-display area NDA, and may be positioned on the third encapsulation layer 175.

The fourth encapsulation layer 177 of the display device 10 may be positioned on the third encapsulation layer 175 and the second insulating layer 123.

In some embodiments, the fourth encapsulation layer 177 of the display device 10 may entirely cover the display area DA and the non-display area NDA of the display panel 100. Therefore, the fourth encapsulation layer 177 of the display device 10 may overlap the edge portion EG of the display panel 100. This may mean that the fourth encapsulation layer 177 overlaps the first edge surface e1, the second edge surface e2, and the third edge surface e3 included in the first substrate 110, and overlaps the undercut UC3 formed by the first edge surface e1 of the first substrate 110 and the second substrate 112.

The fourth encapsulation layer 177 included in the specification may include an inorganic film having hydrophobicity and acid resistance. Therefore, the fourth encapsulation layer 177 may protect a portion of the display panel 100 from being damaged by an etchant during the etching process included in the display device 10. As an example, the fourth encapsulation layer 177 may include amorphous silicon and hydrogenated amorphous silicon nanocrystals. This will be described in detail later.

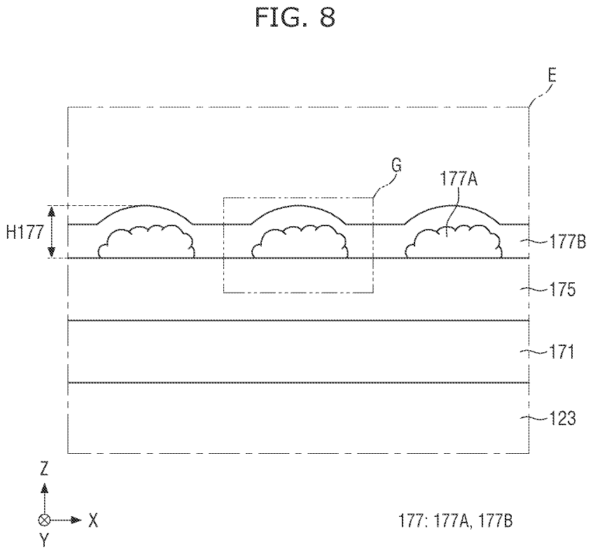

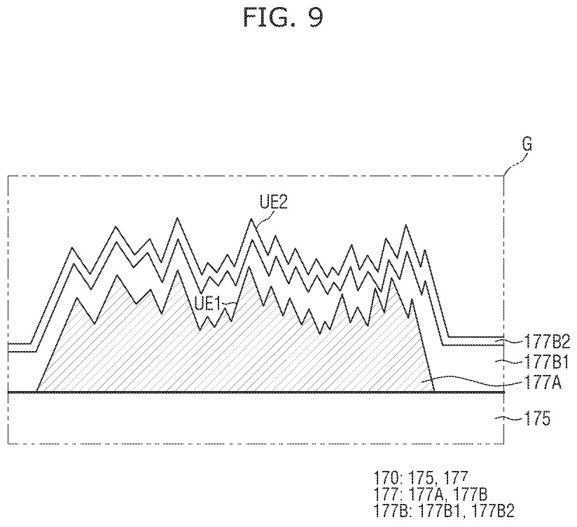

FIG. 8 is an enlarged schematic cross-sectional view of area ‘E’ of FIG. 7. FIG. 9 is an enlarged schematic cross-sectional view of area ‘G’ of FIG. 8.

Referring to FIG. 8, the fourth encapsulation layer 177 may include a first portion 177A and a second portion 177B.

First portions 177A of the fourth encapsulation layer 177 included in the specification may be formed on the third encapsulation layer 175. Although not illustrated in the drawing, the first portions 177A of the fourth encapsulation layer 177 may be formed on the second insulating layer 123 to overlap the edge portion EG of the display panel 100. The first portions 177A of the fourth encapsulation layer 177 may be positioned to be spaced apart from each other. The first portions 177A of the fourth encapsulation layer 177 may be randomly scattered rather than regularly arranged.

For example, the first portion 177A of the fourth encapsulation layer 177 may be formed by partially changing the manufacturing process conditions after forming the third encapsulation layer 175. For example, the first portion 177A of the fourth encapsulation layer 177 may be formed in the same process as the third encapsulation layer 175. Specifically, the first portion 177A of the fourth encapsulation layer 177 may be formed by adjusting silane gas (SiH₄) used in the manufacturing process of forming the third encapsulation layer 175 and an on/off time of power, which is one of the manufacturing processes. For example, the first portion 177A of the fourth encapsulation layer 177 may be continuously formed after the third encapsulation layer 175 is formed.

The first portion 177A of the fourth encapsulation layer 177 may be a nanocrystal having a nano size. As an example, the first portion 177A of the fourth encapsulation layer 177 may be hydrogenated amorphous silicon (a-Si:H) nanocrystals or amorphous silicon (a-Si) nanocrystals.

Referring to FIG. 9, the first portion 177A of the fourth encapsulation layer 177 may include a concavo-convex structure UE1. The concavo-convex structure UE1 may have a randomly arranged concave-convex shape rather than a shape in which regularly arranged protrusions and concavities are repeated. A height of a protruding portion forming the concavo-convex structure UE1 may be formed to be about 40 nm or less, but is not limited thereto.

The first portion 177A of the fourth encapsulation layer 177 may include the concavo-convex structure UE1, which may help maximize acid resistance of the second portion 177B of the fourth encapsulation layer 177 formed in a subsequent process.

The second portion 177B of the fourth encapsulation layer 177 included in the specification may completely cover the first portion 177A of the third encapsulation layer 175 and the first portion 177A of the fourth encapsulation layer 177. Although not illustrated in the drawing, the second portion 177B of the fourth encapsulation layer 177 may also completely cover the second insulating layer 123 and the first portion 177A of the fourth encapsulation layer 177 positioned on the second insulating layer 123.

The second portion 177B of the fourth encapsulation layer 177 may include an inorganic film having acid resistance. As an example, the second portion 177B of the fourth encapsulation layer 177 may include amorphous silicon. The display device 10 included in an embodiment may use a hydrofluoric acid-based etchant in the etching process during the manufacturing process. The second portion 177B of the fourth encapsulation layer 177 includes acid resistance to the hydrofluoric acid-based etchant, which may solve an occurrence of etching defects due to the permeation of the etchant into the display panel 100 during the etching process.

The second portion 177B of the fourth encapsulation layer 177 may cover the first portion 177A with the same thickness along a profile of the first portion 177A. Therefore, the second portion 177B of the fourth encapsulation layer 177 may include a concavo-convex structure UE2. The concavo-convex structure UE2 included in the second portion 177B of the fourth encapsulation layer 177 may have the same structure and characteristics as the concavo-convex structure UE1 included in the first portion 177A. Therefore, the concavo-convex structure UE2 included in the second portion 177B may have a randomly arranged concave-convex shape rather than a shape in which regularly arranged protrusions and concavities are repeated. A height of a protruding portion forming the concavo-convex structure UE2 may be formed to be about 40 nm or less, but is not limited thereto.

The second portion 177B of the fourth encapsulation layer 177 may include the concavo-convex structure UE2, which may allow the second portion 177B of the fourth encapsulation layer 177 to have more maximized acid resistance to the etchant.

As illustrated in FIG. 9, the second portion 177B of the fourth encapsulation layer 177 may include a first layer 177B1 and a second layer 177B2. As described above, the second portion 177B of the fourth encapsulation layer 177 may be an inorganic film having acid resistance. Therefore, the first layer 177B1 and the second layer 177B2 of the second portion 177B may have acid resistance.

However, the second layer 177B2 of the second portion 177B may have acid resistance and hydrophobic properties. This may be formed by treating the second portion 177B of the fourth encapsulation layer 177 with plasma during the manufacturing process of the display device 10. As a result, the second layer 177B2 of the second portion 177B may have acid resistance and hydrophobic properties. Therefore, the second layer 177B2 of the second portion 177B may have higher hydrophobicity than the first layer 177B1 of the second portion 177B.

In some embodiments, the second layer 177B2 of the second portion 177B may be treated with fluorocarbon (CF)-based and hydrocarbon (CH)-based plasma gases, but is not limited thereto. As a result, the second layer 177B2 of the second portion 177B may include a carbon, fluorine, or hydrogen-based functional group, but is not limited thereto.

In some embodiments, a thickness H177 of the fourth encapsulation layer 177 included in the display device 10 may be about 0.2 μm or less. As an example, when the thickness H177 of the fourth encapsulation layer 177 is about 0.2 μm or less, the fourth encapsulation layer 177 may be transparent. Therefore, even if the fourth encapsulation layer 177 of the display device 10 entirely covers the display area DA and the non-display area NDA, this may not affect light efficiency characteristics emitted from the light emitting areas EA1, EA2, EA3, and EA4 of the display device 10.

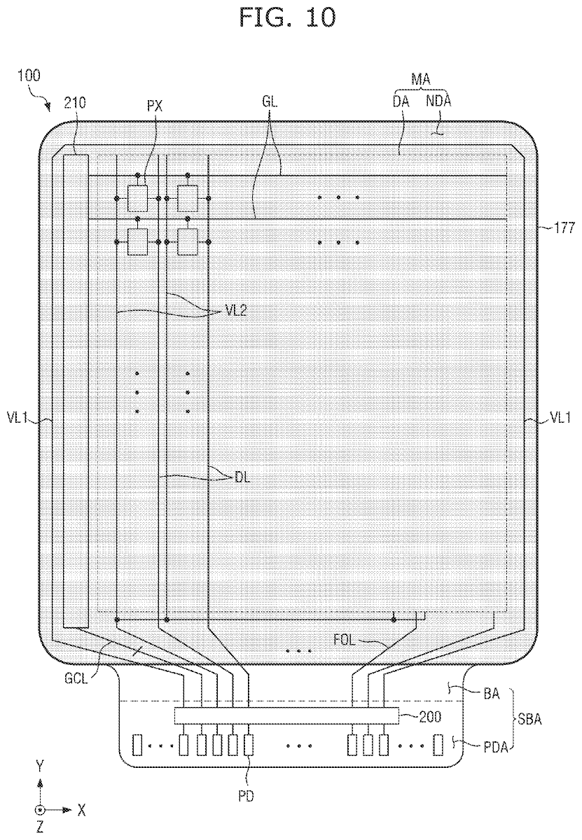

FIG. 10 is a schematic plan view of an area covered by a fourth encapsulation layer 177 in FIG. 4.

Referring to FIG. 10, the fourth encapsulation layer 177 of the display device 10 may entirely cover the lower structure overlapping the display area DA and the non-display area NDA in plan view. In other words, the first portion 177A and the second portion 177B included in the fourth encapsulation layer 177 of the display device 10 may entirely cover the lower structure overlapping the display area DA and the non-display area NDA in plan view. Although not illustrated in the drawing, the fourth encapsulation layer 177 of the display device 10 may overlap the edge portion EG of the display panel 100 in plan view.

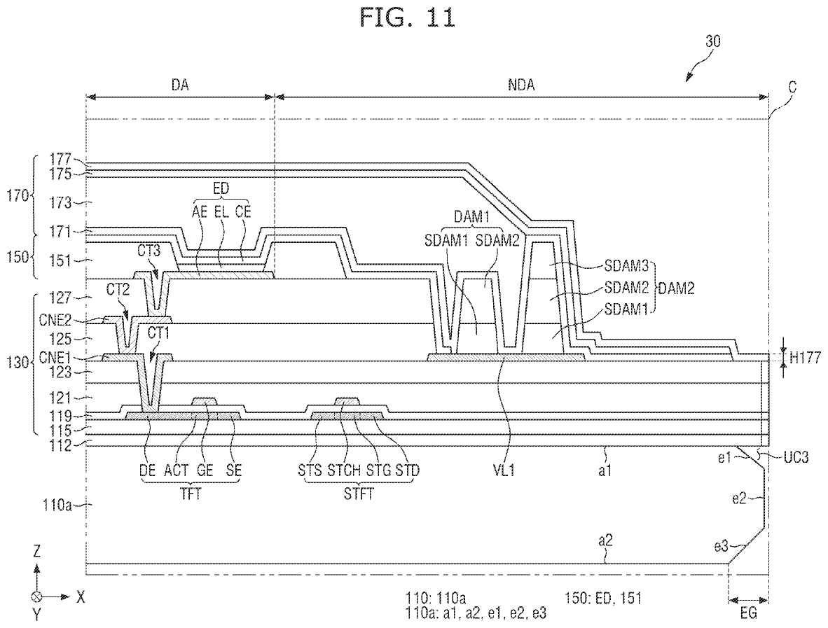

FIG. 11 is an enlarged schematic cross-sectional view of area ‘C’ of FIG. 6 according to another embodiment.

Referring to FIG. 11, the fourth encapsulation layer 177 of a display device 30 included in an embodiment may be positioned on the third encapsulation layer 175 and the second insulating layer 123, and may entirely cover the display area DA and the non-display area NDA of the display panel 100. Therefore, the fourth encapsulation layer 177 of the display device 30 may overlap the edge portion EG of the display panel 100. This may mean that the fourth encapsulation layer 177 of the display device 30 overlaps the first edge surface e1, the second edge surface e2, and the third edge surface e3 included in the first substrate 110, and overlaps the undercut UC3 formed by the first edge surface e1 of the first substrate 110 and the second substrate 112. A lower structure overlapping the fourth encapsulation layer 177 of the display device 30 may include the same structure and characteristics as the display device 10 described above.

However, an embodiment may be different from another embodiment (the display device 10) at least in that the fourth encapsulation layer 177 of the display device 30 included in an embodiment may overlap the edge portion EG of the display panel 100 to cover ends of the second substrate 112, the buffer layer 115, the gate insulating layer 119, the first insulating layer 121, and the second insulating layer 123.

In the display device 30 included in an embodiment, the second substrate 112, the buffer layer 115, the gate insulating layer 119, the first insulating layer 121, and the second insulating layer 123 may overlap the edge portion EG of the display panel to include the ends thereof. The ends of the second substrate 112, the buffer layer 115, the gate insulating layer 119, the first insulating layer 121, and the second insulating layer 123 may be a surface facing an outer portion of the display device 30.

The fourth encapsulation layer 177 included in the display device 30 may cover the ends of the second substrate 112, the buffer layer 115, the gate insulating layer 119, the first insulating layer 121, and the second insulating layer 123, thereby preventing the etchant from permeating into the ends of the second substrate 112, the buffer layer 115, the gate insulating layer 119, the first insulating layer 121, and the second insulating layer 123 during the etching process included in the manufacturing process of the display device 30 to cause defects.

The fourth encapsulation layer 177 of the display device 30 may have the same structure and characteristics as the fourth encapsulation layer 177 of the display device 10 illustrated in FIGS. 8 and 9. Specifically, the fourth encapsulation layer 177 of the display device 30 may include a first portion 177A including the concavo-convex structure UE1 and a second portion 177B including the concavo-convex structure UE2 by covering along the first portion 177A and having acid resistance.

The second portion 177B of the fourth encapsulation layer 177 may include a first layer 177B1 having acid resistance and a second layer 177B2 including acid resistance and treated with plasma. The second layer 177B2 treated with plasma may include hydrophobicity. Therefore, the fourth encapsulation layer 177 of the display device 30 may have hydrophobicity in addition to acid resistance. As a result, the fourth encapsulation layer 177 included in the display device 30 may solve etching defects caused by permeation of an etchant during the manufacturing process of the display device 30. As an example, the first portion 177A of the fourth encapsulation layer 177 may include either hydrogenated amorphous silicon (a-Si:H) nanocrystals or amorphous silicon (a-Si) nanocrystals. The second portion 177B of the fourth encapsulation layer 177 may include amorphous silicon. The second layer 177B2 of the second portion 177B including hydrophobicity through plasma treatment may include hydrogen, fluorine, and carbon ions, but is not limited thereto.

In some embodiments, a thickness H177 of the fourth encapsulation layer 177 included in the display device 30 may be about 0.2 μm or less. The fourth encapsulation layer 177 having the thickness H177 of about 0.2 μm or less may be transparent. Therefore, the fourth encapsulation layer 177 having the thickness H177 of about 0.2 μm or less may overlap the display area DA and may not affect light efficiency emitted from the light emitting areas EA1, EA2, EA3, and EA4 of the display device 30. Other overlapping descriptions will be omitted.

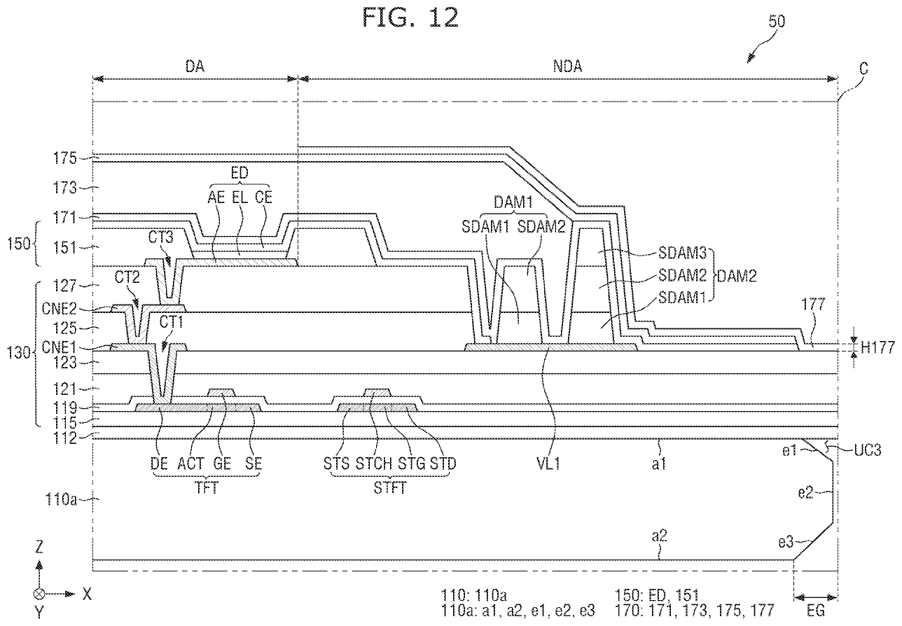

FIG. 12 is an enlarged schematic cross-sectional view of area ‘C’ of FIG. 6 according to still another embodiment.

Referring to FIG. 12, the fourth encapsulation layer 177 of a display device 50 included in an embodiment may be positioned on the third encapsulation layer 175 and the second insulating layer 123, and may overlap the edge portion EG of the display panel 100. This may mean that the fourth encapsulation layer 177 of the display device 50 overlaps the first edge surface e1, the second edge surface e2, and the third edge surface e3 included in the first substrate 110, and overlaps the undercut UC3 formed by the first edge surface e1 of the first substrate 110 and the second substrate 112. A lower structure overlapping the fourth encapsulation layer 177 of the display device 50 may include the same structure and characteristics as the display device 10 described above.

However, the display device 50 included in an embodiment may be different from the display device 10 at least in that the fourth encapsulation layer 177 of the display device 50 does not overlap the display area DA and overlaps only the non-display area NDA.

In some embodiments, in a manufacturing process of the display device 50, after the fourth encapsulation layer 177 is entirely formed to overlap the display area DA and the non-display area NDA, a portion of the fourth encapsulation layer 177 overlapping the display area DA may be etched by a subsequent dry process. Therefore, the fourth encapsulation layer 177 of the display device 50 may not overlap the display area DA, may overlap the non-display area NDA, and may cover a lower structure overlapping the non-display area NDA.

The fourth encapsulation layer 177 of the display device 50 may have the same structure and characteristics as the fourth encapsulation layer 177 of the display device 10 illustrated in FIGS. 8 and 9. Specifically, the fourth encapsulation layer 177 of the display device 50 may include a first portion 177A including the concavo-convex structure UE1 and a second portion 177B including the concavo-convex structure UE2 by covering along the first portion 177A and having acid resistance.

The second portion 177B of the fourth encapsulation layer 177 may include a first layer 177B1 having acid resistance and a second layer 177B2 including acid resistance and treated with plasma. The second layer 177B2 treated with plasma may include hydrophobicity. Therefore, the fourth encapsulation layer 177 of the display device 50 may have hydrophobicity in addition to acid resistance. As a result, the fourth encapsulation layer 177 included in the display device 50 may solve etching defects caused by permeation of an etchant during the manufacturing process of the display device 50. As an example, the first portion 177A of the fourth encapsulation layer 177 may include either hydrogenated amorphous silicon (a-Si:H) nanocrystals or amorphous silicon (a-Si) nanocrystals. The second portion 177B of the fourth encapsulation layer 177 may include amorphous silicon. The second layer 177B2 of the second portion 177B including hydrophobicity through plasma treatment may include hydrogen, fluorine, and carbon ions, but is not limited thereto.

In the display device 50 included in an embodiment, as the fourth encapsulation layer 177 is positioned so as not to overlap the display area DA and to overlap the non-display area NDA, the thickness H177 of the fourth encapsulation layer 177 of the display device 50 may be formed without limitation. Therefore, acid resistance and hydrophobicity of the fourth encapsulation layer 177 of the display device 50 may be further enhanced.

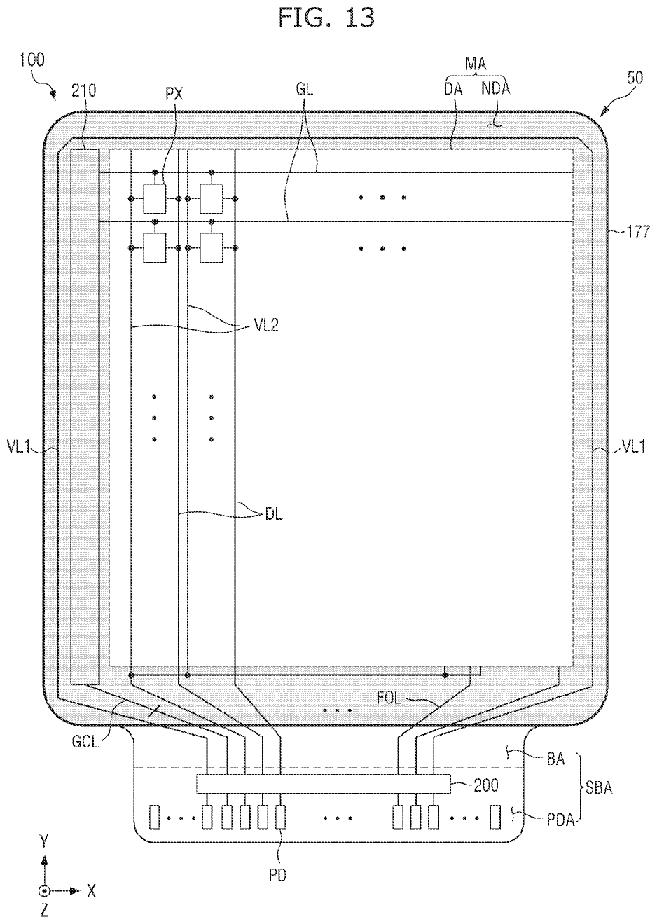

FIG. 13 is a schematic plan view of an area covered by a fourth encapsulation layer 177 of FIG. 12.

Referring to FIG. 13, in plan view, the fourth encapsulation layer 177 included in the display device 50 may overlap the non-display area NDA and be positioned in a mesh shape. In other words, in plan view, the fourth encapsulation layer 177 included in the display device 50 may be positioned in a mesh shape while exposing the display area DA. As described above, after the fourth encapsulation layer 177 included in the display device 50 is entirely formed to overlap the display area DA and the non-display area NDA in plan view, a portion thereof overlapping the display area DA may be removed by a subsequent dry etching process.

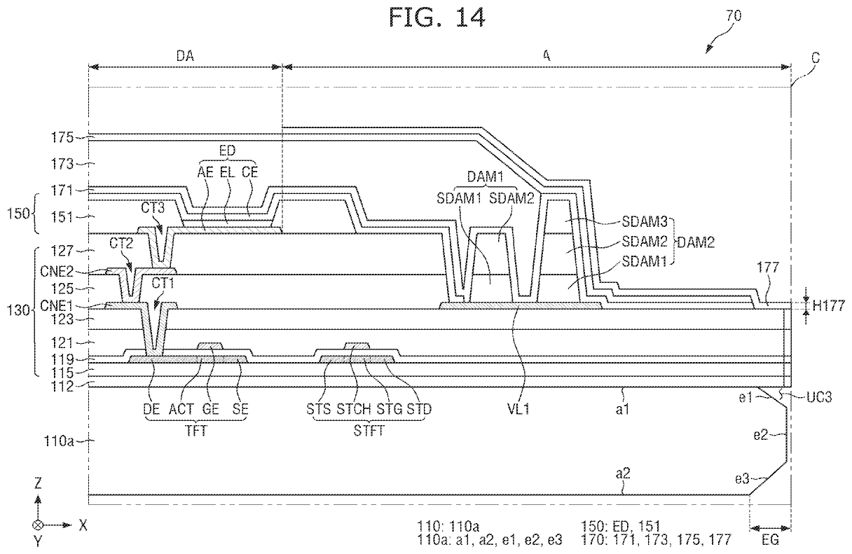

FIG. 14 is an enlarged schematic cross-sectional view of area ‘C’ of FIG. 6 according to still another embodiment.

Referring to FIG. 14, the fourth encapsulation layer 177 of a display device 70 included in an embodiment may be positioned on the third encapsulation layer 175 and the second insulating layer 123, and may overlap the edge portion EG of the display panel 100. This may mean that the fourth encapsulation layer 177 of the display device 70 overlaps the first edge surface e1, the second edge surface e2, and the third edge surface e3 included in the first substrate 110, and overlaps the undercut UC3 formed by the first edge surface e1 of the first substrate 110 and the second substrate 112.

The fourth encapsulation layer 177 of the display device 70 may have the same structure and characteristics as the fourth encapsulation layer 177 of the display device 10 illustrated in FIGS. 8 and 9. Specifically, the fourth encapsulation layer 177 of the display device 70 may include a first portion 177A including the concavo-convex structure UE1 and a second portion 177B including the concavo-convex structure UE2 by covering along the first portion 177A and having acid resistance.

The second portion 177B of the fourth encapsulation layer 177 may include a first layer 177B1 having acid resistance and a second layer 177B2 including acid resistance and treated with plasma. The second layer 177B2 treated with plasma may include hydrophobicity. Therefore, the fourth encapsulation layer 177 of the display device 70 may have hydrophobicity in addition to acid resistance. As a result, the fourth encapsulation layer 177 included in the display device 70 may solve etching defects caused by permeation of an etchant during the manufacturing process of the display device 70. As an example, the first portion 177A of the fourth encapsulation layer 177 may include either hydrogenated amorphous silicon (a-Si:H) nanocrystals or amorphous silicon (a-Si) nanocrystals. The second portion 177B of the fourth encapsulation layer 177 may include amorphous silicon. The second layer 177B2 of the second portion 177B including hydrophobicity through plasma treatment may include hydrogen, fluorine, and carbon ions, but is not limited thereto.

In the display device 70 included in an embodiment, the second substrate 112, the buffer layer 115, the gate insulating layer 119, the first insulating layer 121, and the second insulating layer 123 may overlap the edge portion EG of the display panel 100 to include the ends thereof. The ends of the second substrate 112, the buffer layer 115, the gate insulating layer 119, the first insulating layer 121, and the second insulating layer 123 included in the display device 70 may be a surface facing an outer portion of the display device 70.

The fourth encapsulation layer 177 included in the display device 70 may cover the ends of the second substrate 112, the buffer layer 115, the gate insulating layer 119, the first insulating layer 121, and the second insulating layer 123, which may be the same as the structure and characteristics of the display device 30 described above. Therefore, the fourth encapsulation layer 177 of the display device 70 may prevent the etchant from permeating into the ends of the second substrate 112, the buffer layer 115, the gate insulating layer 119, the first insulating layer 121, and the second insulating layer 123 during the etching process included in the manufacturing process to cause defects.

However, the display device 70 included in an embodiment may be different from the display device 30 at least in that the fourth encapsulation layer 177 of the display device 70 does not overlap the display area DA and overlaps only the non-display area NDA.

In some embodiments, in a manufacturing process of the display device 70, after the fourth encapsulation layer 177 is entirely formed to overlap the display area DA and the non-display area NDA, a portion of the fourth encapsulation layer 177 overlapping the display area DA may be etched by a subsequent dry process. Therefore, the fourth encapsulation layer 177 of the display device 70 may not overlap the display area DA, and may cover a lower structure overlapping the non-display area NDA.

In the display device 70 included in an embodiment, as the fourth encapsulation layer 177 is positioned so as not to overlap the display area DA and to overlap the non-display area NDA, the thickness H177 of the fourth encapsulation layer 177 of the display device 70 may be formed without limitation. Therefore, acid resistance and hydrophobicity of the fourth encapsulation layer 177 of the display device 70 may be further enhanced.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a first substrate including a display area and a non-display area surrounding the display area;
a second substrate disposed on the first substrate;
a display element layer disposed on the second substrate and overlapping the display area;
a first encapsulation layer disposed on the display element layer, overlapping the non-display area, and including an inorganic material; and
a second encapsulation layer disposed on the first encapsulation layer, including a concavo-convex structure, and including an inorganic material, wherein
the first substrate includes:
a first surface overlapping an edge portion of the first substrate and facing the second substrate, and
a first inclined surface extending to the first surface,
an inclination angle formed by the first surface and the first inclined surface is an obtuse angle, and
the first inclined surface overlaps the second encapsulation layer in a direction perpendicular to the first substrate.

2. The display device of claim 1, wherein the first inclined surface and the second substrate form an undercut.

3. The display device of claim 2, wherein the undercut overlaps the second encapsulation layer in the direction perpendicular to the first substrate.

4. The display device of claim 3, wherein the second encapsulation layer completely covers the first encapsulation layer.

5. The display device of claim 3, wherein the second encapsulation layer includes an inorganic material having acid resistance against a fluorine-based etchant.

6. The display device of claim 5, wherein the second encapsulation layer includes amorphous silicon.

7. The display device of claim 1, wherein the second encapsulation layer includes:
a plurality of first layers including the concavo-convex structure and that are spaced apart from each other in a direction parallel to the first substrate;
a second layer completely covering the plurality of first layers and including the concavo-convex structure; and
a third layer disposed on the second layer and including the concavo-convex structure.

8. The display device of claim 7, wherein the third layer has higher hydrophobicity than the plurality of first layers.

9. The display device of claim 8, wherein the third layer includes carbon, fluorine, and hydrogen ions.

10. The display device of claim 7, wherein the second layer physically contacts the first encapsulation layer.

11. The display device of claim 1, wherein
the first substrate includes a second surface facing the first surface and a second inclined surface overlapping the edge portion of the first substrate and extended to the second surface, and
an inclination angle formed by the second surface and the second inclined surface is an obtuse angle.

12. The display device of claim 11, wherein the second inclined surface overlaps the second encapsulation layer in the direction perpendicular to the first substrate.

13. The display device of claim 1, wherein a thickness of the second encapsulation layer in the direction perpendicular to the first substrate is about 0.2 μm or less.

14. The display device of claim 13, wherein
the second encapsulation layer overlaps the display area and the non-display area in plan view, and
the second encapsulation layer completely covers the first encapsulation layer in plan view.

15. The display device of claim 14, wherein the second encapsulation layer overlaps the edge portion of the first substrate and covers a side surface of the second substrate.

16. The display device of claim 1, wherein the second encapsulation layer is disposed in a mesh shape to overlap the non-display area while exposing the display area in plan view.

17. The display device of claim 16, wherein the second encapsulation layer overlaps the edge portion of the first substrate and covers a side surface of the second substrate.

18. A display device, comprising:
a first substrate including a main area and a pad area;
a second substrate disposed on the first substrate and including a bending area disposed between the main area and the pad area;
a display element layer disposed on the second substrate and overlapping the main area;
a first encapsulation layer disposed on the display element layer and including an inorganic material; and
a second encapsulation layer disposed on the first encapsulation layer, including a concavo-convex structure, and including an inorganic material, wherein
the first substrate includes a first sub-substrate and a second sub-substrate spaced apart from each other with the bending area disposed between the first sub-substrate and the second sub-substrate,
the first sub-substrate includes:
a surface facing the second substrate, and
a first inclined surface facing the bending area and extended to the surface, and
the first sub-substrate and the second encapsulation layer overlap each other in a direction perpendicular to the first substrate.

19. The display device of claim 18, wherein
an inclination angle formed by the first inclined surface and the surface is an obtuse angle, and
the second substrate and the first inclined surface form an undercut.

20. The display device of claim 19, wherein
the first sub-substrate includes a second inclined surface opposing the first inclined surface,
the second inclined surface is extended to the surface in a direction opposite to a direction in which the first inclined surface is disposed,
an inclination angle formed by the surface and the second inclined surface is an obtuse angle, and
the second inclined surface and the second encapsulation layer overlap each other in the direction perpendicular to the first substrate.
